(19) United States
(12) Patent Application Publication
(10) Pub. No.: US 2026/0107444 A1
(43) Pub. Date: Apr. 16, 2026

(54) MANUFACTURING METHOD OF SEMICONDUCTOR STRUCTURE

(71) Applicant: NANYA TECHNOLOGY CORPORATION, New Taipei City (TW)

(72) Inventor: Pei-Jhu SIE, New Taipei City (TW)

(21) Appl. No.: 18/912,606

(22) Filed: Oct. 11, 2024

(51) Int. Cl. H10B 12/00; H01L 21/3205; H01L 21/768

(52) U.S. Cl. CPC H10B 12/482; H10B 12/485; H10P 14/416; H10W 20/077

(57) ABSTRACT

A manufacturing method of a semiconductor structure is provided. The method includes following steps. A substrate is provided, and the substrate has a first array region, a second array region, and a periphery region. A first lower conductive layer is formed on the substrate, the first lower conductive layer continuously has a first portion in the first array region, a second portion in the second array region, and a third portion in the periphery region. The first portion of the first lower conductive layer and the second portion of the first lower conductive layer are removed. A second lower conductive layer is formed on the substrate. The second lower conductive and the first lower conductive layer comprise the same material such that the second lower conductive and the first lower conductive layer form a lower conductive layer collectively.

### BACKGROUND

### FIELD OF INVENTION

The present disclosure relates to a manufacturing method of a semiconductor structure.

### DESCRIPTION OF RELATED ART

In a dynamic random access memory (DRAM), a moat between the array region and the peripheral region can reduce bit line defect issues in the array region. However, in the current process, it is hard to control the etch depth of the moat during the formation of the lower conductive layer. Therefore, a significant amount of time is required to measure the etch depth of the moat structure.

### SUMMARY

In accordance with an aspect of the present disclosure, a manufacturing method of a semiconductor structure is provided. The method includes following steps. A substrate is provided, the substrate has a first array region, a second array region, and a periphery region, wherein the second array region surrounds the first array region and the periphery region surrounds the second array region. A first lower conductive layer is formed on the substrate, the first lower conductive layer continuously has a first portion in the first array region, a second portion in the second array region, and a third portion in the periphery region, wherein the top surface of the first portion is higher than the top surface of the second portion and the third portion, and the top surface of the second portion is coplanar with the top surface of the third portion. The first portion of the first lower conductive layer and the second portion of the first lower conductive layer are removed. A second lower conductive layer is formed on the substrate, the second lower conductive layer continuously has a first portion on the substrate in the first array region, a second portion on the substrate in the second array region, and a third portion on the third portion of the first lower conductive layer, wherein the top surface of the third portion of the second lower conductive layer is higher than the top surface of the first portion of the second lower conductive layer, and the first portion of the second lower conductive layer is higher than the top surface of the second portion of the second lower conductive layer, and wherein the second lower conductive and the first lower conductive layer comprise the same material such that the second lower conductive and the first lower conductive layer form a lower conductive layer collectively.

According to some embodiments of the present disclosure, further including forming a sacrificial layer on the first lower conductive layer prior to removing the first portion of the first lower conductive layer and the second portion of the first lower conductive layer, wherein the sacrificial layer continuously has a first portion in the first array region, a second portion in the second array region, and a third portion in the periphery region, wherein the top surface of the first portion is higher than the top surface of the second portion and the third portion, and the top surface of the second portion is coplanar with the top surface of the third portion.

According to some embodiments of the present disclosure, further includes forming a photoresist on the third portion of the first lower conductive layer prior to removing the first portion of the first lower conductive layer and the second portion of the first lower conductive layer.

According to some embodiments of the present disclosure, wherein the first lower conductive layer and the second lower conductive layer include polysilicon.

According to some embodiments of the present disclosure, further includes doping a portion of the lower conductive layer in the first array region to form a doped lower conductive layer.

According to some embodiments of the present disclosure, further includes forming an upper conductive layer on the lower conductive layer and the doped lower conductive layer.

According to some embodiments of the present disclosure, further includes forming a cap layer on the upper conductive layer.

According to some embodiments of the present disclosure, further includes performing an etching process to form a first bit line structure and a second bit line structure in the first array region, wherein the first bit line structure comprises the cap layer, the upper conductive layer, and the lower conductive layer, and wherein the second bit line structure comprises the cap layer, the upper conductive layer, and the doped lower conductive layer.

According to some embodiments of the present disclosure, wherein a first angle between the sidewall of lower conductive layer of the first bit line structure and the top surface of the substrate is different from a second angle between the sidewall of the doped lower conductive layer of the second bit line structure and the top surface of the substrate.

According to some embodiments of the present disclosure, further includes forming a first spacer on the sidewall of the first bit line structure and the sidewall of the second bit line structure; and forming a second spacer on the first spacer of the first bit line structure and the first spacer of the second bit line structure.

In accordance with an aspect of the present disclosure, a manufacturing method of a semiconductor structure is provided. The method includes following steps. A substrate is provided, the substrate has a first array region, a second array region, and a periphery region, wherein the top surface of the substrate in the first array region is higher than the top surface of the substrate in the second array region and the periphery region, and the top surface of the substrate in the second array region is coplanar with the top surface of the substrate in the periphery region. A first lower conductive layer is formed on the substrate, the first lower conductive layer continuously has a first portion in the first array region, a second portion in the second array region, and a third portion in the periphery region, wherein the first portion, the second portion, and the third portion of the first lower conductive layer have the same thickness. The first portion of the first lower conductive layer and the second portion of the first lower conductive layer are removed. A second lower conductive layer is formed on the substrate, the second lower conductive layer continuously has a first portion on the substrate in the first array region, a second portion on the substrate in the second array region, and a third portion on the third portion of the first lower conductive layer, wherein the first portion, the second portion, and the third portion of the second lower conductive layer have the same thickness, and wherein the second lower conductive and the first lower conductive layer comprise polysilicon such that the second lower conductive and the first lower conductive layer form a lower conductive layer collectively.

According to some embodiments of the present disclosure, further includes doping a portion of the lower conductive layer in the first array region to form a doped lower conductive layer; forming an upper conductive layer on the lower conductive layer and the doped lower conductive layer; and forming a cap layer on the upper conductive layer.

According to some embodiments of the present disclosure, further includes performing an etching process to form a first bit line structure and a second bit line structure in the first array region wherein the first bit line structure comprises the cap layer, the upper conductive layer, and the lower conductive layer, and wherein the second bit line structure comprises the cap layer, the upper conductive layer, and the doped lower conductive layer.

According to some embodiments of the present disclosure, wherein a first angle between the sidewall of the lower conductive layer of the first bit line structure and the top surface of the substrate is between 90 degrees to 180 degrees.

According to some embodiments of the present disclosure, wherein a second angle between the sidewall of the doped lower conductive layer of the second bit line structure and the top surface of the substrate is 90 degrees.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top-view schematic diagram of a semiconductor structure, in accordance with some embodiments;

FIG. 2 is a cross-sectional view schematic diagram of a semiconductor structure along the A-A line of FIG. 1, in accordance with some embodiments;

FIG. 3 is a cross-sectional view schematic diagram of a semiconductor structure after forming a sacrificial layer, in accordance with some embodiments;

FIG. 4 is a cross-sectional view schematic diagram of a semiconductor structure after removing a portion of the sacrificial layer and the first lower conductive layer, in accordance with some embodiments;

FIG. 5 is a cross-sectional view schematic diagram of a semiconductor structure after forming a second lower conductive layer, in accordance with some embodiments;

FIG. 6 is a cross-sectional view schematic diagram of a semiconductor structure after forming a hard mask layer, in accordance with some embodiments;

FIG. 7 is a cross-sectional view schematic diagram of a semiconductor structure after forming an upper conductive layer, in accordance with some embodiments;

FIG. 8 is a cross-sectional view schematic diagram of a semiconductor structure after forming a cap layer, in accordance with some embodiments;

FIG. 9 is a cross-sectional view schematic diagram of a semiconductor structure after performing an etching process, in accordance with some embodiments; and

FIG. 10 is a cross-sectional view schematic diagram of a semiconductor structure after forming a first spacer and a second spacer, in accordance with some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

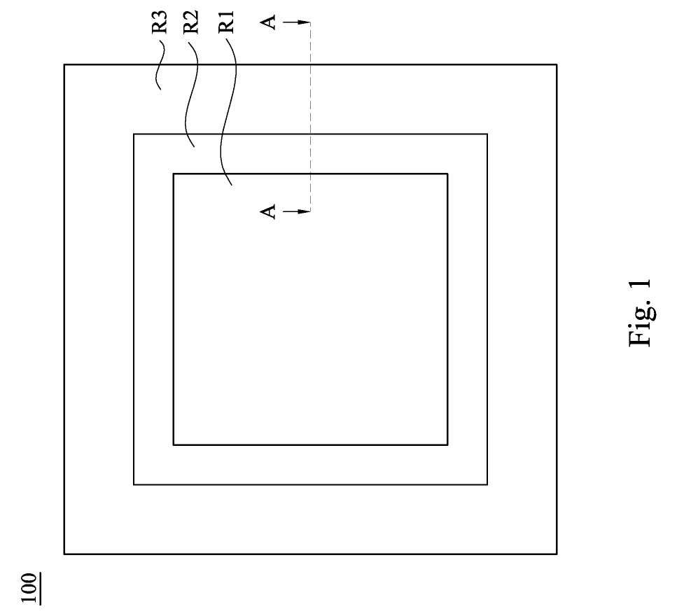

FIG. 1 to FIG. 10 are schematic diagrams of various intermediate stages in the formation of a semiconductor structure 100, in accordance with some embodiments. The semiconductor structure 100 can be applied to or part of the integrated circuit (IC), such as logic circuits, resistors, capacitors, sensors, memory device (such as dynamic random access memory (DRAM)). It should be understood that in order to simplify the graph, some components of the semiconductor structure 100 are not shown in FIG. 1 to FIG. 10, and other embodiments of the semiconductor structure 100 may include additional components.

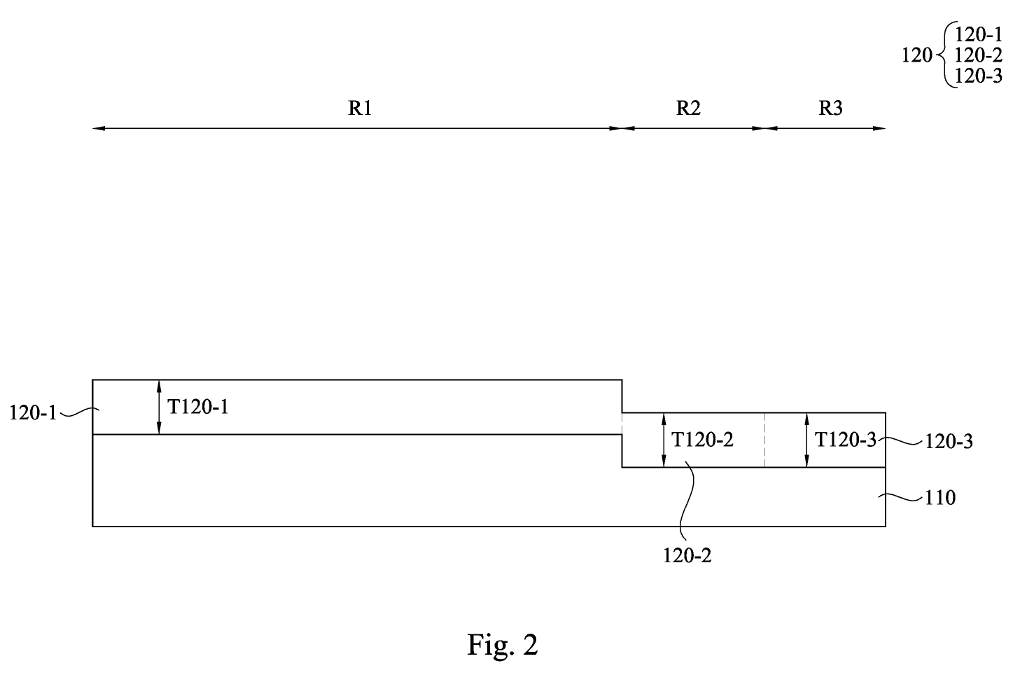

FIG. 1 is a top-view schematic diagram of a semiconductor structure 100. FIG. 2 is a cross-sectional view schematic diagram of the semiconductor structure 100 along the A-A line of FIG. 1. As shown in FIG. 1 and FIG. 2, the semiconductor structure 100 includes a first array region R1, a second array region R2, and a periphery region R3, wherein the second array region R2 surrounds the first array region R1, and the periphery region R3 surrounds the second array region R2. The semiconductor structure 100 includes a substrate 110. The top surface of the substrate 110 in the first array region R1 is higher than the top surface of the substrate 110 in the second array region R2 and the periphery region R3. The top surface of the substrate 110 in the second array region R2 is basically coplanar with the top surface of the substrate 110 periphery region R3. In other words, a stair structure is between the first array region R1 and the second array region R2.

In some embodiments, the substrate 110 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 110 can be doped (e.g., containing p-type or n-type dopants) or undoped. In some embodiments, the semiconductor material of the substrate 110 may include silicon, germanium, compound semiconductors (including silicon carbide, gallium arsenide, gallium phosphide, indium phosphide, indium arsenide, and/or indium antimonide), alloy semiconductors or a combination thereof. The substrate 110 can also be formed of other materials, such as sapphire, indium tin oxide, and the like.

As shown in FIG. 2, a first lower conductive layer 120 is formed on the substrate. A first portion 120-1 of the first lower conductive layer 120 is located in the first array region R1. A second portion 120-2 of the first lower conductive layer 120 is located in the second array region R2. A third portion 120-3 of the first lower conductive layer 120 is located in the periphery region R3. Similar to the substrate 110, the top surface of the first portion 120-1 of the first lower conductive layer 120 in the first array region R1 is higher than the top surface of the second portion 120-2 and the third portion 120-3 of the first lower conductive layer 120. The top surface of the second portion 120-2 of the first lower conductive layer 120 is basically coplanar with the top surface of the third portion 120-3 of the first lower conductive layer 120. As shown, the thickness T120-1 of the first portion 120-1, the thickness T120-2 of the second portion 120-2, and the thickness T120-3 of the third portion 120-3 are basically the same. In other words, the first portion 120-1, the second portion 120-2, and the third portion 120-3 of the first lower conductive layer 120 are continuously formed on the substrate 110.

In some embodiments, the first lower conductive layer 120 may be formed using a suitable deposition process, such as chemical vapor deposition (CVD), plasma enhanced chemical vapor deposition (PECVD), atomic layer deposition (ALD), or the like. In some embodiments, the first lower conductive layer 120 includes conductive materials, such as poly-silicon.

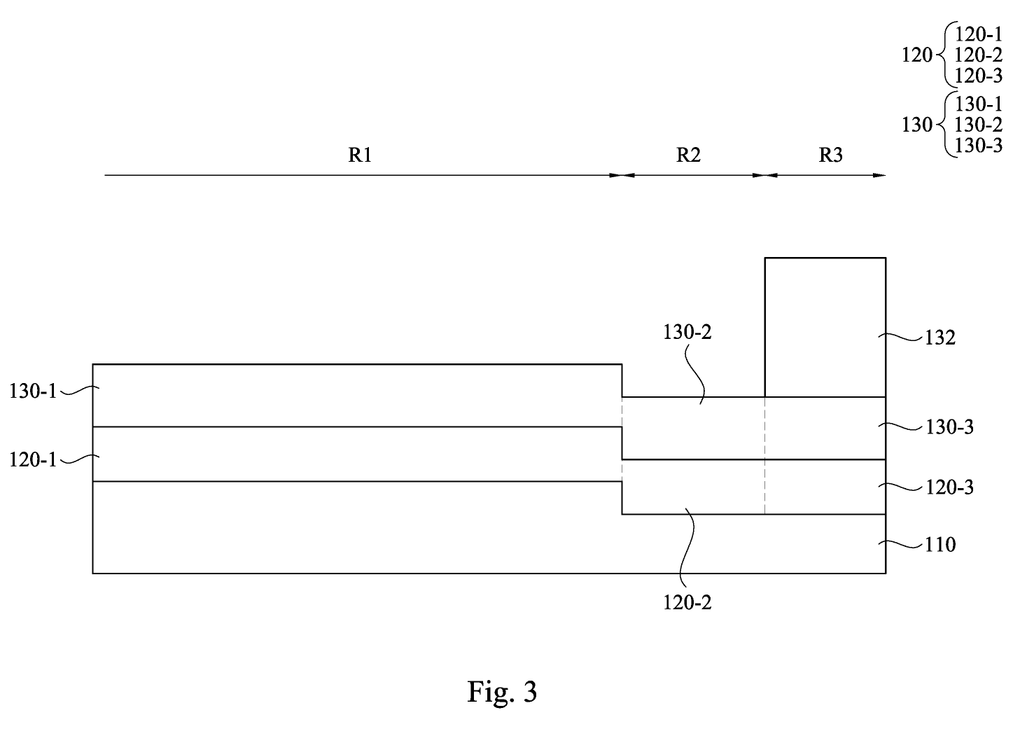

Referring to FIG. 3, a sacrificial layer 130 may be formed on the first lower conductive layer 120. A first portion 130-1 of the sacrificial layer 130 is located in the first array region R1. A second portion 130-2 of the sacrificial layer 130 is located in the second array region R2. A third portion 130-3 of the sacrificial layer 130 is located in the periphery region R3. A photoresist 132 may be formed on the sacrificial layer 130 in the periphery region R3. In other words, the first portion 130-1 of the sacrificial layer 130 and the second portion 130-2 of the sacrificial layer 130 are exposed. Similar to the first lower conductive layer 120, the top surface of the first portion 130-1 of the sacrificial layer 130 in the first array region R1 is higher than the top surface of the second portion 130-2 and the third portion 130-3 of the sacrificial layer 130. The top surface of the second portion 130-2 of the sacrificial layer 130 is basically coplanar with the top surface of the third portion 130-3 of the sacrificial layer 130.

In some embodiments, the sacrificial layer 130 and the photoresist 132 may be formed using a suitable deposition process, such as chemical vapor deposition (CVD), plasma enhanced chemical vapor deposition (PECVD), atomic layer deposition (ALD), or the like. In some embodiments, the sacrificial layer 130 includes dielectric materials, such as oxide.

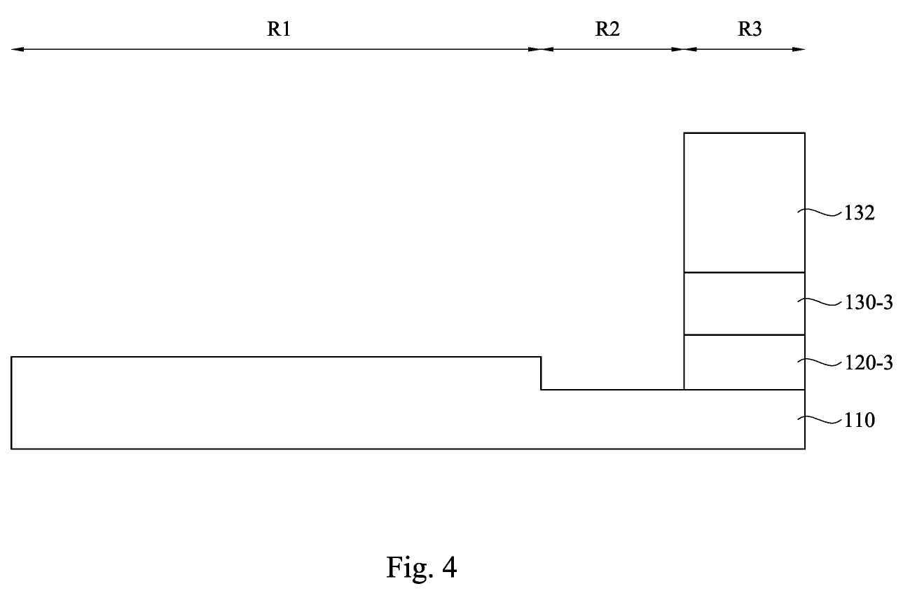

Referring to FIG. 4, a portion of the sacrificial layer 130 and a portion of the first lower conductive layer 120 are removed. In detail, the first portion 130-1 and the second portion 130-2 of the sacrificial layer 130 are removed. The first portion 120-1 and the second portion 120-2 of the first lower conductive layer 120 are removed. The first portion 130-1 and the second portion 130-2 of the sacrificial layer 130 and the first portion 120-1 and the second portion 120-2 of the first lower conductive layer 120 may be removed using a suitable directional dry etching process, such as plasma reactive etching, ion-beam etching, or the like.

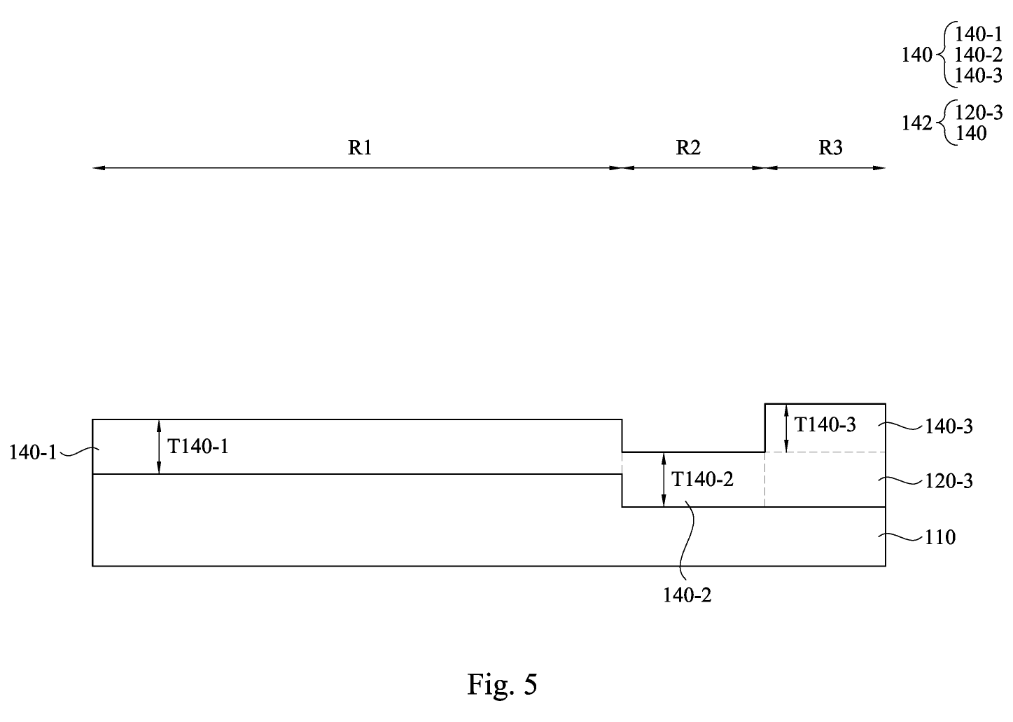

Referring to FIG. 5, a second lower conductive layer 140 is formed on the substrate 110. In detail, a first portion 140-1 of the second lower conductive layer 140 is formed on the substrate 110 in the first array region R1. A second portion 140-2 of the second lower conductive layer 140 is formed on the substrate in the second array region R2. A third portion 140-3 of the second lower conductive layer 140 is formed on the third portion 120-3 of the first lower conductive layer 120.

As shown in FIG. 5, the top surface of the third portion 140-3 of the second lower conductive layer 140 is higher than the top surface of the first portion 140-1 of the second lower conductive layer 140. The top surface of the first portion 140-1 of the second lower conductive layer 140 is higher than the top surface of the second portion 140-2 of the second lower conductive layer 140. In other words, the top surface of the second portion 140-2 of the second lower conductive layer 140 is the lowest. The second portion 140-2 forms a moat structure. The moat structure can reduce bit line structure defects in subsequent process. As shown, the thickness T140-1 of the first portion 140-1, the thickness T140-2 of the second portion 140-2, and the thickness T140-3 of the third portion 140-3 are basically the same.

In some embodiments, the second lower conductive layer 140 may be formed using a suitable deposition process, such as chemical vapor deposition (CVD), plasma enhanced chemical vapor deposition (PECVD), atomic layer deposition (ALD), or the like. In some embodiments, the second lower conductive layer 140 includes conductive materials, such as polysilicon. In the present disclosure, the first lower conductive layer 120 and the second lower conductive layer 140 are formed by the same material. Therefore, the second lower conductive layer 140 and the third portion 120-3 of the first lower conductive layer 120 are collectively referred to as lower conductive layer 142 in the following.

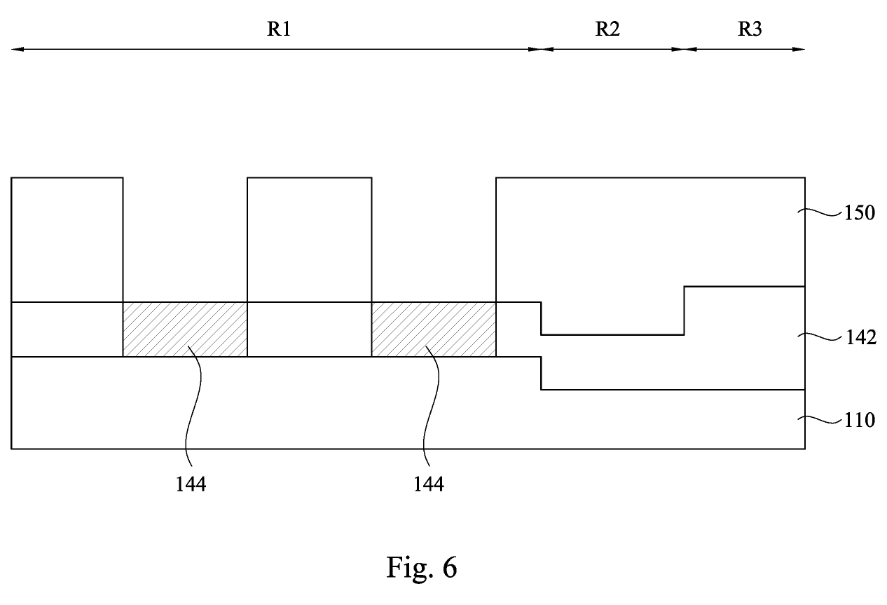

Referring to FIG. 6, a hard mask layer 150 is formed on the lower conductive layer 142, and an opening 152 is formed in the hard mask layer 150 to expose a portion of the lower conductive layer 142. The opening 152 is formed in the first array region R1. Then, the portion of the lower conductive layer 142 is doped through the opening 152 to form a doped lower conductive layer 144. The doped lower conductive layer 144 may include N-type materials, such as phosphorus, arsenic, antimony, bismuth, and other suitable materials.

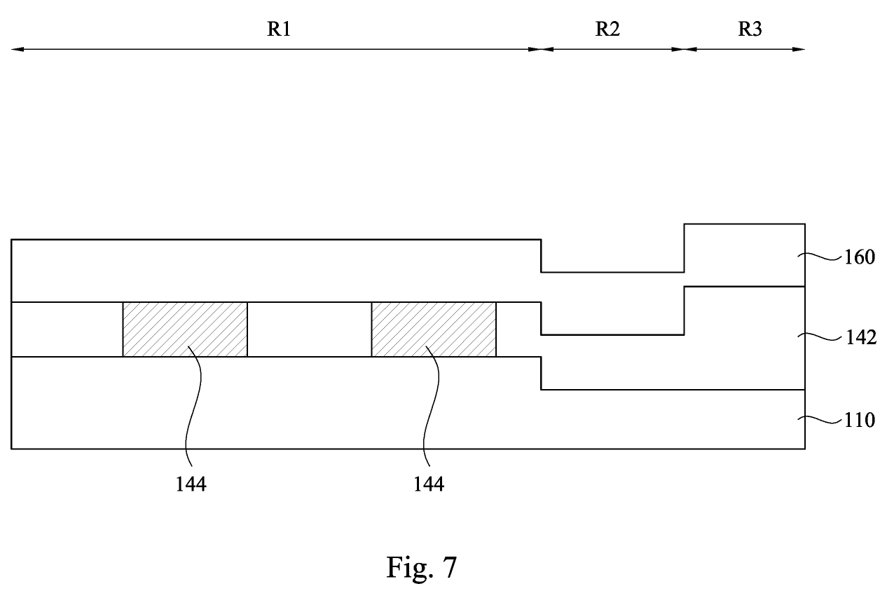

Referring to FIG. 7, an upper conductive layer 160 is formed on the lower conductive layer 142 and the doped lower conductive layer 144. The upper conductive layer 160 has the same thickness in the first array region R1, the second array region R2, and the periphery region R3. So the top surface of the upper conductive layer 160 has the same shape as the top surface of the lower conductive layer 142 underneath. In some embodiments, the upper conductive layer 160 may be formed using a suitable deposition process, such as chemical vapor deposition (CVD), plasma enhanced chemical vapor deposition (PECVD), atomic layer deposition (ALD), or the like. In some embodiments, the upper conductive layer 160 includes conductive materials, such as metal. For example, the upper conductive layer 160 may include tungsten.

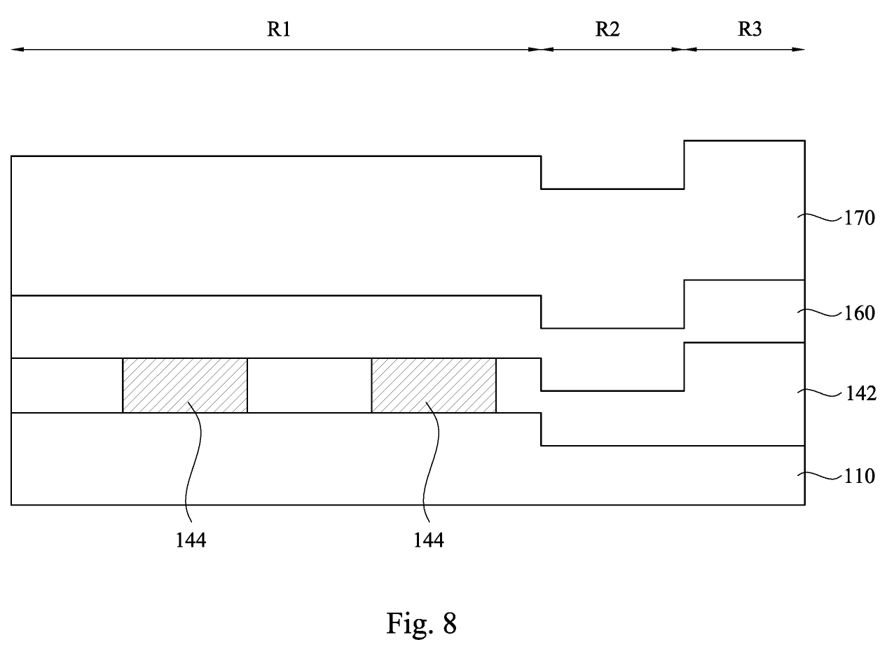

Referring to FIG. 8, a cap layer 170 is formed on the upper conductive layer 160. The cap layer 170 has the same thickness in the first array region R1, the second array region R2, and the periphery region R3. So the top surface of the cap layer 170 has the same shape as the top surface of the upper conductive layer 160 underneath. In some embodiments, the cap layer 170 may be formed using a suitable deposition process, such as chemical vapor deposition (CVD), plasma enhanced chemical vapor deposition (PECVD), atomic layer deposition (ALD), or the like. In some embodiments, the cap layer 170 includes dielectric materials, such as nitride.

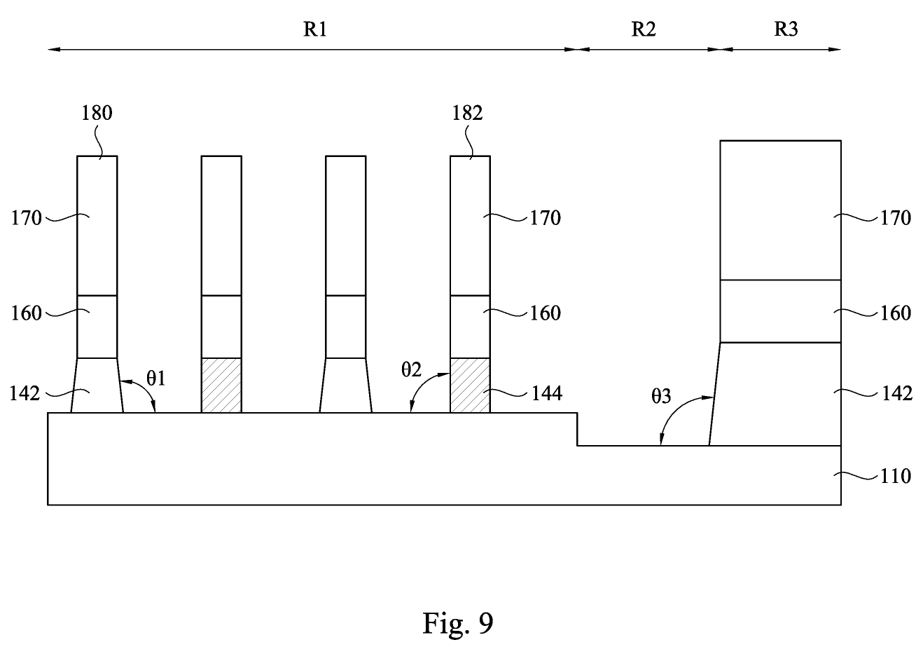

Referring to FIG. 9, an etching process may be performed to form a first bit line structure 180 and a second bit line structure 182. The first bit line structure 180 includes the lower conductive layer 142, the upper conductive layer 160, and the cap layer 170. The second bit line structure 182 includes the doped lower conductive layer 144, the upper conductive layer 160, and the cap layer 170. As shown, the first angle θ1 between the sidewall of the lower conductive layer 142 of the first bit line structure 180 and the top surface of the substrate 110 is greater than 90 degrees. The second angle θ2 between the sidewall of the doped lower conductive layer 144 of the second bit line structure 182 and the top surface of the substrate 110 substantially equals to 90 degrees. The third angle θ3 between the sidewall of the lower conductive layer 142 in. the periphery region R3 is greater than 90 degrees, and the third angle θ3 is substantially equals to the first angle θ1. In some embodiments, the etching process may be an all-in-one (AIO) dry etching process. In other embodiments, the etching process may combine more than one dry etching process such that the cap layer 170, the upper conductive layer 160, the doped lower conductive layer 144, and the lower conductive layer 142 are removed by different etching stages.

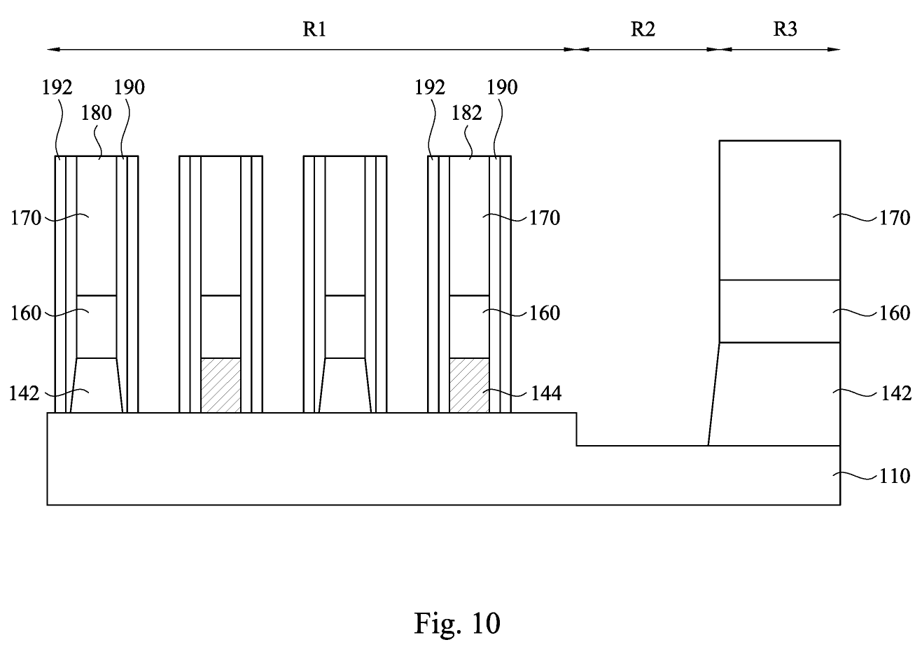

Referring to FIG. 10, a first spacer 190 is formed on the sidewall of the first bit line structure 180 and the sidewall of the second bit line structure 182, respectively. A second spacer 192 is formed on the sidewall of the first spacer 190. In some embodiments, the first spacer 190 and the second spacer 192 may be formed using a suitable deposition process, such as chemical vapor deposition (CVD), plasma enhanced chemical vapor deposition (PECVD), atomic layer deposition (ALD), or the like. In some embodiments, the first spacer 190 and the second spacer 192 may include suitable dielectric materials. For example, the first spacer 190 may include oxide, and the second spacer may include nitride.

The present disclosure provides a manufacturing method of a semiconductor structure. With the method provided in this disclosure, the lower conductive layer is formed by the first lower conductive layer and the second conductive layer. Therefore, the depth of the moat can be controlled. The performance of the AIO etching process may increase, thereby reducing parasitic capacitance. With the method disclosed in this disclosure, the thickness of the lower conductive layer in the array region and the depth of the moat can be controlled, which can reduce the variation from wafer-to-wafer and improve the overall performance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing semiconductor structure, comprising:
providing a substrate, the substrate having a first array region, a second array region, and a periphery region, wherein the second array region surrounds the first array region and the periphery region surrounds the second array region;
forming a first lower conductive layer on the substrate, the first lower conductive layer continuously having a first portion in the first array region, a second portion in the second array region, and a third portion in the periphery region, wherein the top surface of the first portion is higher than the top surface of the second portion and the third portion, and the top surface of the second portion is coplanar with the top surface of the third portion;
removing the first portion of the first lower conductive layer and the second portion of the first lower conductive layer; and
forming a second lower conductive layer on the substrate, the second lower conductive layer continuously having a first portion on the substrate in the first array region, a second portion on the substrate in the second array region, and a third portion on the third portion of the first lower conductive layer,
wherein the top surface of the third portion of the second lower conductive layer is higher than the top surface of the first portion of the second lower conductive layer, and the first portion of the second lower conductive layer is higher than the top surface of the second portion of the second lower conductive layer, and
wherein the second lower conductive and the first lower conductive layer comprise the same material such that the second lower conductive and the first lower conductive layer form a lower conductive layer collectively.

2. The method of claim 1, further comprising:
forming a sacrificial layer on the first lower conductive layer prior to removing the first portion of the first lower conductive layer and the second portion of the first lower conductive layer,
wherein the sacrificial layer continuously has a first portion in the first array region, a second portion in the second array region, and a third portion in the periphery region, wherein the top surface of the first portion is higher than the top surface of the second portion and the third portion, and the top surface of the second portion is coplanar with the top surface of the third portion.

3. The method of claim 2, further comprising
forming a photoresist on the third portion of the first lower conductive layer prior to removing the first portion of the first lower conductive layer and the second portion of the first lower conductive layer.

4. The method of claim 1, wherein the first lower conductive layer and the second lower conductive layer comprise polysilicon.

5. The method of claim 1, further comprising:
doping a portion of the lower conductive layer in the first array region to form a doped lower conductive layer.

6. The method of claim 5, further comprising:
forming an upper conductive layer on the lower conductive layer and the doped lower conductive layer.

7. The method of claim 6, further comprising:
forming a cap layer on the upper conductive layer.

8. The method of claim 7, further comprising:
performing an etching process to form a first bit line structure and a second bit line structure in the first array region,
wherein the first bit line structure comprises the cap layer, the upper conductive layer, and the lower conductive layer, and
wherein the second bit line structure comprises the cap layer, the upper conductive layer, and the doped lower conductive layer.

9. The method of claim 8, wherein a first angle between the sidewall of lower conductive layer of the first bit line structure and the top surface of the substrate is different from a second angle between the sidewall of the doped lower conductive layer of the second bit line structure and the top surface of the substrate.

10. The method of claim 8, further comprising:
forming a first spacer on the sidewall of the first bit line structure and the sidewall of the second bit line structure; and
forming a second spacer on the first spacer of the first bit line structure and the first spacer of the second bit line structure.

11. A method of manufacturing semiconductor structure, comprising:
providing a substrate, the substrate having a first array region, a second array region, and a periphery region, wherein the top surface of the substrate in the first array region is higher than the top surface of the substrate in the second array region and the periphery region, and the top surface of the substrate in the second array region is coplanar with the top surface of the substrate in the periphery region;
forming a first lower conductive layer on the substrate, the first lower conductive layer continuously having a first portion in the first array region, a second portion in the second array region, and a third portion in the periphery region, wherein the first portion, the second portion, and the third portion of the first lower conductive layer have the same thickness;
removing the first portion of the first lower conductive layer and the second portion of the first lower conductive layer; and
forming a second lower conductive layer on the substrate, the second lower conductive layer continuously having a first portion on the substrate in the first array region, a second portion on the substrate in the second array region, and a third portion on the third portion of the first lower conductive layer,
wherein the first portion, the second portion, and the third portion of the second lower conductive layer have the same thickness, and
wherein the second lower conductive and the first lower conductive layer comprise polysilicon such that the second lower conductive and the first lower conductive layer form a lower conductive layer collectively.

12. The method of claim 11, further comprising:
doping a portion of the lower conductive layer in the first array region to form a doped lower conductive layer;
forming an upper conductive layer on the lower conductive layer and the doped lower conductive layer; and
forming a cap layer on the upper conductive layer.

13. The method of claim 12, further comprising:
performing an etching process to form a first bit line structure and a second bit line structure in the first array region,
wherein the first bit line structure comprises the cap layer, the upper conductive layer, and the lower conductive layer, and
wherein the second bit line structure comprises the cap layer, the upper conductive layer, and the doped lower conductive layer.

14. The method of claim 13, wherein a first angle between the sidewall of the lower conductive layer of the first bit line structure and the top surface of the substrate is between 90 degrees to 180 degrees.

15. The method of claim 13, wherein a second angle between the sidewall of the doped lower conductive layer of the second bit line structure and the top surface of the substrate is 90 degrees.
